(19) United States
(12) Patent Application Publication
(10) Pub. No.: US 2006/0183268 A1
(43) Pub. Date: Aug. 17, 2006

(54) Salicide process for image sensor

(75) Inventor: Howard E. Rhodes, Boise, ID (US)

Correspondence Address: PERKINS COIE LLP / OMNIVISION TECHNOLOGIES, INC., P.O. BOX 1247, SEATTLE, WA, 98111-1247, US

(73) Assignee: OmniVision Technologies, Inc., Sunnyvale, CA (US)

(21) Appl. No.: 11/058,117

(22) Filed: Feb. 14, 2005

(51) Int. Cl. H01L 21/00; H01L 21/44

(52) U.S. Cl. 438/98; 438/73; 438/664; 438/682

(57) ABSTRACT

A self-aligned silicide (salicide) process is used to form a metal salicide for a CMOS image sensor consistent with a conventional CMOS image sensor process flow. An insulator layer is deposited over the pixel array of the image sensor. Portions of the insulator layer are removed using a photoresist mask and a metal layer is deposited. The photoresist mask protects the photosensitive regions of the image sensor. The metal layer is annealed to form a metal silicide.

### TECHNICAL FIELD

The present invention relates to image sensors, and more particularly, to an image sensor that uses a salicide process.

### BACKGROUND

Image sensors have become ubiquitous. They are widely used in digital still cameras, cellular phones, security cameras, medical, automobile, and other applications. The technology used to manufacture image sensors, and in particular CMOS image sensors, has continued to advance at great pace. For example, the demands of higher resolution and lower power consumption have encouraged the further miniaturization and integration of the image sensor.

With the further integration, an important aspect of image sensor performance is the ability to read out quickly the signals from the pixel array. It is not unusual for a pixel array to include over five million separate pixels. Many image sensors use a metal salicide process to improve the speed of the periphery transistors and to provide a low resistance routing line and a local interconnect.

However, it is known in the prior art that the photodiode sensor region should be protected from the salicidation. If the photodiode were to be salicided (typically with a cobalt or titanium salicide), the performance of the image sensor would be degraded. Specifically, a cobalt or titanium salicide (CoSi₂ or TiSi₂) is opaque to light and would thus block light from the underlying photodiode, decreasing sensitivity. Further, the salicide would also increase dark current. For these reasons, a protective coating (typically oxide or nitride or an oxide-nitride composite film) is placed over the photodiode and often over the entire imaging array to protect the sensitive regions during the salicide process.

Still, there is substantial yield loss due to transistor gates that are not completely salicided, which results in an increase in the RC time constant for those gates which make the image sensor nearly inoperable. Gate response time to voltage driving pulses are slowed to the point that they do not respond at the correct timing intervals in the designed circuit. This is particularly an issue with transistor gates that are long and/or wide and that are not uniformly salicided across the entire wafer.

A prior art process for a metal salicide used in an image sensor is shown in FIGS. 1-7. Turning to FIG. 1, a cross-section of an image sensor shows an array section 101 and a periphery section 103. The array section 101 includes the pixel array and various interconnect resources. The periphery section 103 includes logic, timing circuits, control circuits, signal processing, and the like used to control and read out the signal from the array section 101. Note that the cross-sectional view of FIG. 1 is of a four-transistor pixel, but other pixel designs may also be used.

The prior art salicide formation process is typically performed after the spacer etch and the implant steps have been completed. Because the implant step requires high temperatures to activate the dopants, these high temperatures would damage the salicide. Moreover, without the spacers in place, there would be short circuits between the source and drain regions with the transistor gates. Thus, the salicide process is typically performed after the pixels have been formed.

As seen in FIG. 1, in accordance with the prior art, an insulator layer 115 is deposited over the array section 101 and the periphery section 103. Then, as seen in FIG. 2, an organic film 201 (such as a photoresist or bottom anti-reflective coating) is formed over the insulator layer 115. Because of the uneven surface of the image sensor (caused by various underlying transistor or interconnect structures), the deposited film 201 is not uniform.

Low-lying areas such as the photodiode and source/drain regions are covered with a thick organic film. Over the gate regions and polysilicon interconnect structure 113, the thickness of the organic film 201 depends on the size of those polysilicon features. On larger features, the organic film 201 can reach its full thickness approximately equal to the thickness over the photodiode areas. However, over smaller features, such as the transfer gate and reset gate of the pixel, the organic film 201 is thinner.

Turning to FIG. 3, according to the prior art process, an etchback step is performed to remove a portion of the organic film 201. However, there remains a portion of the organic film 201 over the polysilicon interconnect region 113. If the etching time is increased to remove this organic film over the polysilicon interconnect 113, then the organic film 201 that is over the photodiode may also be removed.

The Figures and description herein is but one example of the problem. The wide polysilicon interconnect 113 may be part of a long interconnect linking the transfer gates to periphery driver circuits. It may also be a long, wide interconnect for the reset or row select gates. In all of these cases, there is the issue that current manufacturing processes do not have the process margin to guarantee that the organic film 201 remains over the photodiode, while being completely removed over the polysilicon interconnect 113.

FIGS. 4-7 further illustrate the limitations of the prior art. Specifically, in FIG. 4, the exposed insulator layer 115 is removed. The insulator layer 115 could be, for example, silicon dioxide. The removal can be done using a wet etch (HF etchant) process or a dry etch process which, for example, would be a plasma process using a fluorine-containing gas.

FIG. 4 shows that the organic film 201 remains in place while the oxide over the transistor gates are removed. The removal of the oxide layer 115 is intended to keep the photodiode region protected while allowing the polysilicon gates to be exposed. As seen in FIG. 4, because the organic layer 201 remains atop of the polysilicon interconnect structure 113, the oxide layer 115 over the polysilicon interconnect structure 113 remains.

After removal of the organic layer 201, as seen in FIG. 5, a photoresist layer 501 is patterned such that the insulator layer 115 in the periphery section 103 is removed. After the photoresist layer 501 is stripped, a metal such as titanium, cobalt, or nickel, is deposited. The image sensor is then exposed to a heat source and where the metal is in contact with silicon, a metal salicide is formed as shown in FIG. 6. The unreacted metal can be removed using selective wet etchants, such as APM (ammonium hydroxide and hydrogen peroxide mixture). The result of the selective removal of the unreactant metal is shown in FIG. 7. At this point, the difficulty with the prior art is clearly evident. There is no salicide formed over the wide polysilicon interconnect 113 in the array.

### BRIEF DESCRIPTION OF THE DRAWINGS

FIGS. 1-7 are cross-sectional views illustrating a prior art method for forming a salicide structure in a CMOS image sensor.

FIGS. 8-12 are cross-sectional views illustrating a method in accordance with the present invention for forming a salicide structure in a CMOS image sensor.

### DETAILED DESCRIPTION

In the following description, numerous specific details are provided in order to give a thorough understanding of embodiments of the invention. One skilled in the relevant art will recognize, however, that the invention may be practiced without one or more of the specific details, or with other methods, components, materials, etc. In other instances, well known structures, materials, or operations are not shown or described in order to avoid obscuring aspects of the invention.

References throughout the specification to “one embodiment” or “an embodiment” means that a particular feature, structure, or characteristic described in connection with the embodiment and included in at least one embodiment of the present invention. Thus, the appearances of the phrase “in one embodiment” or “in an embodiment” in various places throughout the specification are not necessarily all referring to the same embodiment. Furthermore, the particular features, structures, or characteristics may be combined in any suitable manner in one or more embodiments.

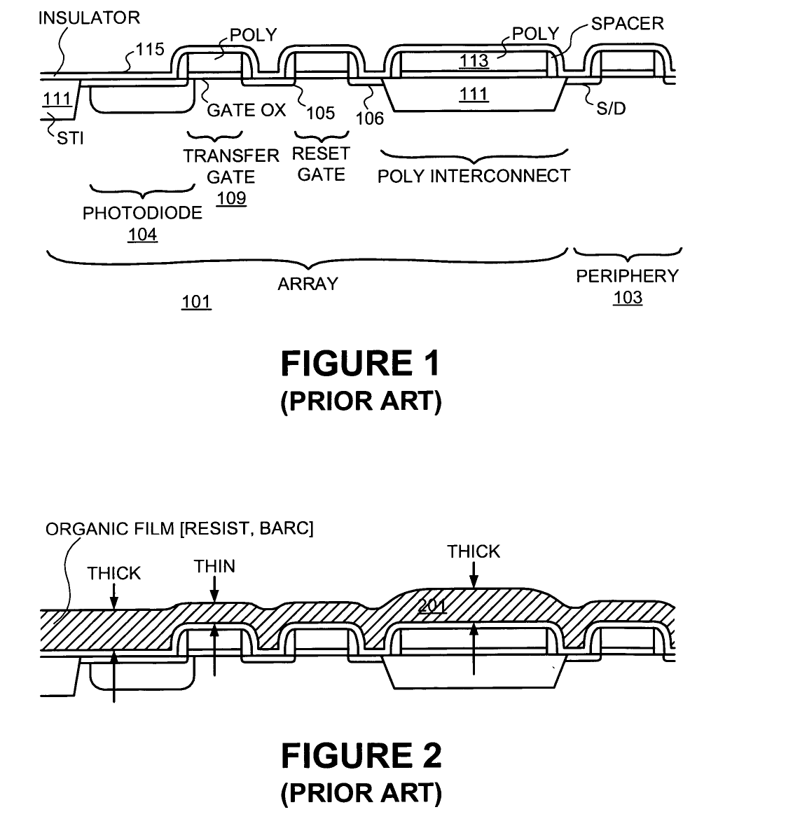

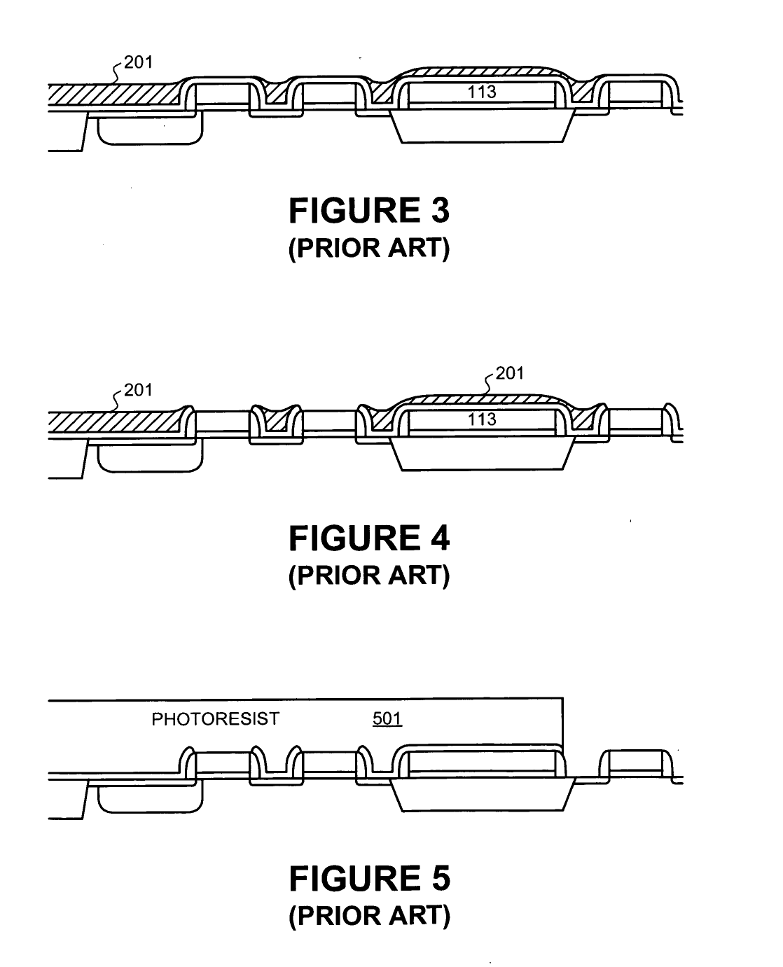

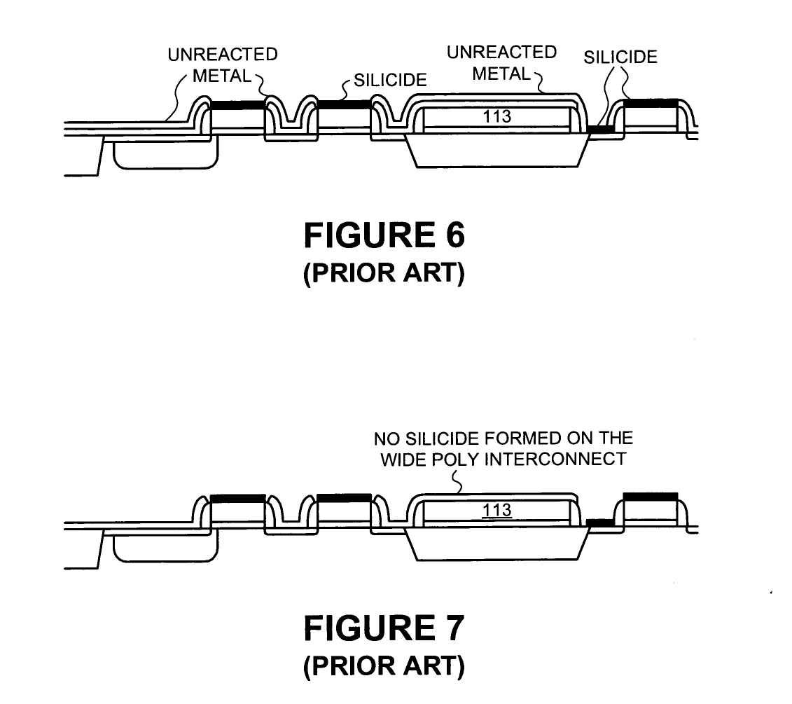

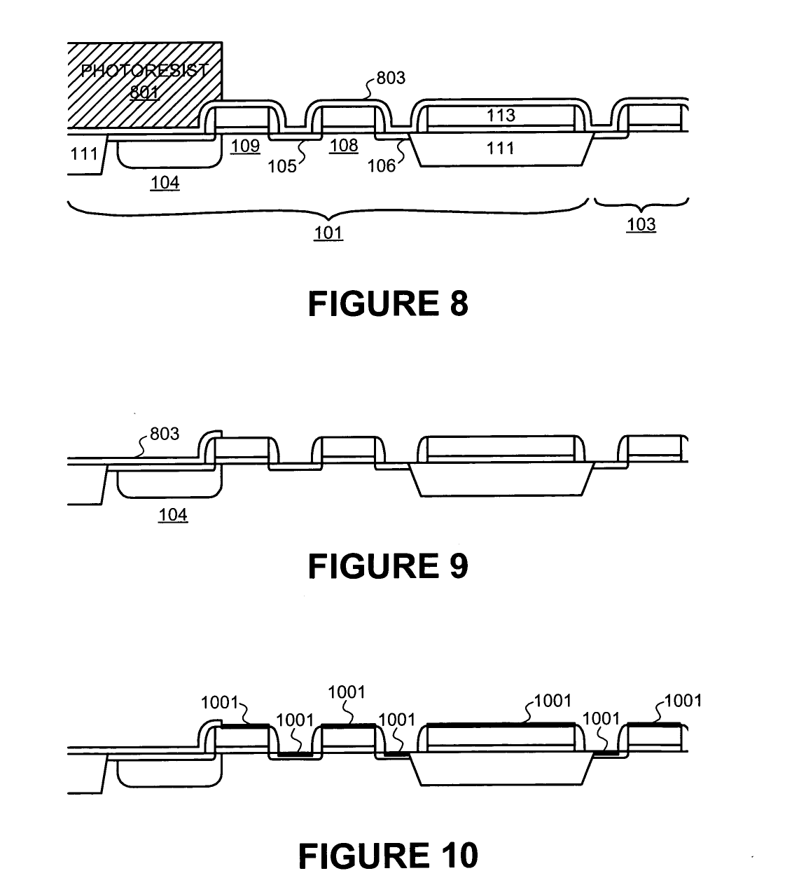

Turning to FIG. 8, a cross-sectional view of a representative CMOS image sensor is shown. Like FIG. 1 described above, the image sensor includes a pixel array section 101 and a periphery section 103. While FIG. 8 (and the following figures) illustrates a cross-sectional view of a four transistor (4T) pixel design, the teachings and structures of the present invention can be equally applied to CMOS image sensors using 3T, 5T, 6T, 7T, or any other pixel design. For example, the present invention may be used in connection with pixels that include a reset transistor, a row select transistor, a global shutter transistor, a high dynamic range transistor, a transistor connected to a lateral overflow drain (lateral overflow transistor), or a transistor used to switch the floating diffusion (floating diffusion switch transistor).

It should be noted that the teachings of the present invention may be applied to any integrated circuit that has formed a silicide structure. The application of the present invention to a CMOS image sensor is meant to provide only a single example of how the present invention may be applied. As will be seen below, the present invention may be generalized as follows: (1) an insulator layer is formed over an underlying substrate with various raised silicon and/or polysilicon features; (2) an organic layer is formed over the insulator layer that is patterned to protect certain sensitive regions; (3) an etching step is performed to remove the insulator layer from the unprotected raised features; (4) a metal layer is deposited over the top surface of the raised features; (5) an anneal is performed to form a metal silicide where the metal layer contacts the top surface of the silicon and/or polysilicon; and (6) the unreacted metal layer is removed.

Returning to the description of the specific application of the present invention to a CMOS image sensor, in the 4T design shown in FIG. 8, the pixel array section 101 (showing a single pixel) includes a photosensor 104, a reset transistor 108, a transfer transistor 109, a floating node 105, an n+ diffusion 106 connected to the V_{dd} supply voltage (not shown), a polysilicon interconnect 113, and shallow trench isolation (STI) regions 111. The photosensor 104 may be a photodiode, a photogate, or a photoconductor.

Note that FIG. 8 only shows a portion of a 4T pixel and that other components (such as the amplification transistor) are not shown for clarity purposes. The other components and operation of the pixel are not particularly germane to the present invention and are well known by those of ordinary skill in the art.

Similarly, in the periphery section 103, a single transistor is shown in cross section. This transistor is meant to be exemplary of the types of circuits and devices formed in the periphery. Thus, the transistor is merely representative of the types of devices existing in the periphery section 103.

As seen in FIG. 8, an insulator layer 803 is blanket deposited onto the CMOS image sensor. The insulator layer 803 can be deposited using various deposition technologies, such as chemical vapor deposition (CVD), plasma enhanced chemical vapor deposition (PECVD), or high density plasma chemical vapor deposition (HDPCVD). In one embodiment, the insulator layer 803 is an oxide. After the formation of the insulator layer 803, a photoresist layer 801 is patterned such that the photodiode 104 is protected. The transistors (108, 109, and the periphery region) and polysilicon interconnect 113 are exposed.

Then, as seen in FIG. 9, a portion of the insulator layer 803 is removed using the photoresist 801 as a mask. The insulator layer 803 remains over the photodiode 104. The insulator layer 803 may be removed using a wet etchant such as HF. Alternatively, a dry etch using a fluorine gas may be used in a plasma process.

Next, turning to FIG. 10, a process, such as sputtering, is used to deposit a layer of metal over the image sensor. While the layer of metal can be any one of the types of metals used in semiconductor processing, such as nickel, cobalt, tungsten, titanium, or molybdenum, in one embodiment, the metal is formed from cobalt. Note that because the insulator layer 803 has been removed, the metal can directly contact the polysilicon layers, as well as the source and drain regions of the transistors.

Still referring to FIG. 10, a thermal anneal is performed to cause the metal to interact with the exposed silicon substrate and the exposed polysilicon gates. This results in the formation of a salicide 1001 on those regions where the metal and silicon (or polysilicon) are in contact.

Next, while not shown in FIG. 10, the metal is then removed. This can be done, for example, using an appropriate wet etching technique. One example of such a wet etching would be NH₄OH (ammonium hydroxide) in H₂O₂ (hydrogen peroxide).

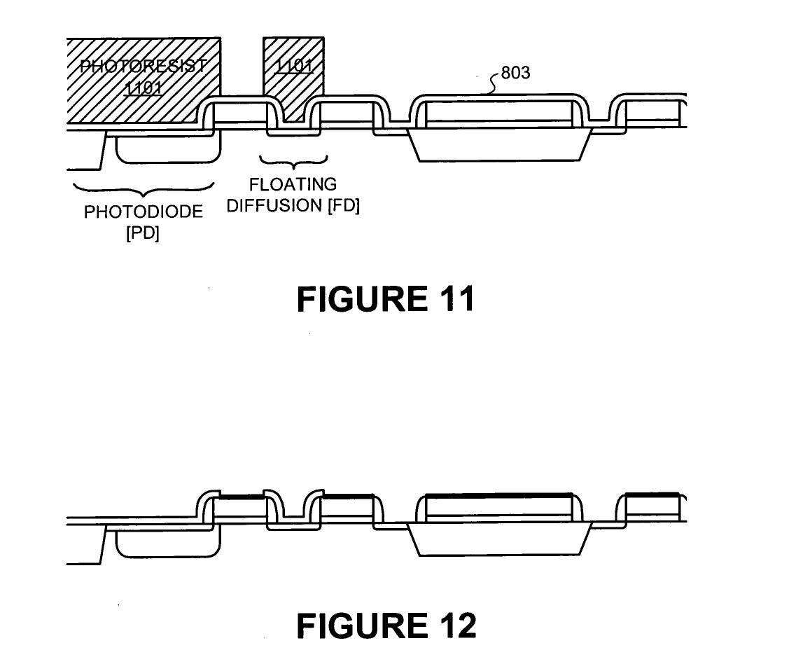

In an alternative embodiment shown in FIGS. 11 and 12, a photoresist layer 1101 not only covers the photodiode, but also the floating diffusion (floating node) 105. The floating node 105 is a region that is required to have a low junction leakage to enhance image sensor performance. As such, it would be advantageous to protect the floating node as well. Thus, after removal of portions of the insulator layer 803, the floating node 105 and the photodiode 104 still have the protective insulator layer 803 formed thereon. The resulting structure, after metal deposition, reaction, and removal is seen in FIG. 12.

As can be seen by the above description and Figures, a self-aligned silicide (salicide) process is disclosed that is consistent with a conventional CMOS image sensor process flow. As noted previously, it is possible to use many types of metal, or even alloys of metal. For example, titanium/tungsten, titanium/molybdenum, cobalt/tungsten, or cobalt/molybdenum may be used.

From the foregoing, it will be appreciated that specific embodiments of the invention have been described herein for purposes of illustration, but that various modifications may be made without deviating from the spirit and scope of the invention. For example, the present invention has been described using a salicide, but the invention may be applied to a silicide structure and the two terms as used herein are interchangeable. As a further example, while the present invention has been described in conjunction with a CMOS image sensor, the present invention may be used with other types of solid state sensors, such CCDs. Accordingly, the invention is not limited except as by the appended claims.

I/We claim:

1. A method of forming a silicide for a pixel array formed in a silicon substrate, said pixel array having at least one polysilicon structure, the method comprising:
forming an insulator layer over said pixel array;
forming a photoresist over said insulator layer, said photoresist protecting at least the photosensitive regions of said pixel array;
using said photoresist as a mask to remove portions of said insulator layer to expose said at least one polysilicon structure and a portion of said silicon substrate;
forming a metal layer over said insulator layer, said at least one polysilicon structure, and said portion of said semiconductor substrate; and
forming a metal silicide by annealing said metal layer, said metal silicide being formed where said metal layer contacts said silicon substrate and said at least one polysilicon structure.

2. The method of claim 1 further including the step of removing said metal layer that is not reacted to form said metal silicide.

3. The method of claim 1 wherein said insulator layer is an oxide layer.

4. The method of claim 1 wherein said metal layer is cobalt, nickel, titanium, molybdenum, tantalum, or tungsten, or alloys thereof.

5. The method of claim 1 wherein said pixel array is comprised of pixels that include a floating diffusion.

6. The method of claim 5 wherein said photoresist also protects said floating diffusion.

7. The method of claim 1 wherein said polysilicon structure is a polysilicon interconnect.

8. The method of claim 5 wherein said pixels include a reset transistor and a transfer transistor having gates formed from polysilicon and said insulator layer is removed from the tops of said gates using said photoresist as a mask.

9. A method of forming a silicide during manufacture of an image sensor formed in a silicon substrate, said image sensor having a pixel array section and a periphery section, said image sensor having at least one polysilicon structure, the method comprising:
forming an insulator layer over said pixel array section and said periphery section;
forming a photoresist over said insulator layer, said photoresist protecting at least the photosensitive regions of said pixel array section;
using said photoresist as a mask to remove portions of said insulator layer to expose said at least one polysilicon structure and a portion of said silicon substrate;
forming a metal layer over said insulator layer, said at least one polysilicon structure, and said portion of said semiconductor substrate; and
forming a metal silicide by annealing said metal layer, said metal silicide being formed where said metal layer contacts said silicon substrate and said at least one polysilicon structure.

10. The method of claim 9 further including the step of removing said metal layer that is not reacted to form said metal silicide.

11. The method of claim 9 wherein said insulator layer is an oxide layer.

12. The method of claim 9 wherein said metal layer is cobalt, nickel, titanium, molybdenum, tantalum, or tungsten, or alloys thereof.

13. The method of claim 9 wherein said pixel array section is comprised of pixels that include a floating diffusion.

14. The method of claim 13 wherein said photoresist also protects said floating diffusion.

15. The method of claim 9 wherein said polysilicon structure is a polysilicon interconnect.

16. The method of claim 13 wherein said pixels include a reset transistor and a transfer transistor having gates formed from polysilicon and said insulator layer is removed from the tops of said gates using said photoresist as a mask.
